(19) United States
(12) Patent Application Publication
(10) Pub. No.: US 2007/0238251 A1
(43) Pub. Date: Oct. 11, 2007

(54) Method of forming sub-100nm narrow trenches in semiconductor substrates

(75) Inventors: Chu Yaw Liau, Singapore (SG); Patsda Ai Ching Liew, Kuching (MY); Fwu-Iuan Hshieh, Saratoga, CA (US)

Correspondence Address: Bo-In Lin, 13445 Mandoli Drive, Los Altos Hills, CA, 94022, US

(73) Assignee: M-MOS Semiconductor Sdn. Bhd.

(21) Appl. No.: 11/399,046

(22) Filed: Apr. 5, 2006

(51) Int. Cl. H01L 21/336

(52) U.S. Cl. 438/270

(57) ABSTRACT

A method to form a narrow trench within a semiconductor substrate includes exemplary steps of: (a) A CVD layer such as SiO₂ represented as “CVD1” is deposited on top of a semiconductor surface followed by a different type of CVD layer such as SiON or Si₃N₄ (represented by “CVD2” deposited on top of “CVD1”. (b) A 0.2 um trench is formed by partially etching a trench in the CVD deposited layers with a substantial “CVD1” thickness left in order to act as a hard mask layer in the later stage. (c) A thin layer of polysilicon is then deposited in the trench such that the polysilicon covers conformally on the trench wall, trench bottom and on top of the “CVD2” layer. (d) The polysilicon at the trench bottom is then blanket etched to expose the “CVD1” substrate again. (e) The remaining “CVD1” substrate, which is exposed now at the trench bottom, will go through a “CVD1” etching process with good selectivity to Polysilicon and “CVD2” in order to expose the semiconductor substrate at trench bottom. (f) The narrow “CVD1” trench, which is now formed, will go through another etching process to etch the semiconductor substrate with the narrow “CVD1” trench acting as a hard mask. In preferred embodiments, the method of the present invention is used to manufacture trenched MOSFET device.

### BACKGROUND OF THE INVENTION

1. Field of the Invention

This invention relates generally to fabrication process of power semiconductor devices. More particularly, this invention relates to a novel manufacturing process to form narrow trenches with a width under one hundred nanometers suitable for implementing in the processing steps for manufacturing semiconductor power devices such as the MOSFET devices.

2. Description of the Related Art

Conventional technologies are still challenged by a costly manufacturing process in defining a sub-100 nm trench. The expensive processing steps are caused by the requirements of a very costly ArF photolithographic exposure tool and/or Phase Shift Mask (PSM) or other Resolution Enhancement Technique (RET). The high cost exposure tool and/or the PSM or RET technologies are needed to define a photoresist pattern with reasonably good profile.

There is an urgent demand to reduce the manufacturing costs because the narrow trenches are commonly desired during fabrication of a wide array of semiconductor devices. Hence, although in a specific example discussed below, the utility of narrow trenches is in connection with trench MOSFET devices, it is understood that the narrow trenches have broad applications throughout various devices in the semiconductor field.

A trenched MOSFET (metal-oxide-semiconductor-field-effect transistor) is a transistor in which the channel is formed vertically and the gate is formed in a trench extending between the source and drain. The trench with a thin insulation layer such as an oxide layer as a linen layer and filled with a conductor such as polysilicon (i.e., polycrystalline silicon), allows less constricted current flow and thereby provides lower values of specific on-resistance. Examples of trench MOSFET transistors are disclosed, for example, in U.S. Patents including U.S. Pat. Nos. 6,977,203, 5,072,266, 5,541,425, and 5,866,931, the disclosures of these Patents are hereby incorporated by reference.

As a specific example, FIG. 1A illustrates the narrow trench MOSFET structure disclosed in U.S. Pat. No. 6,977,203. The structure includes an N+ doped silicon substrate 200, upon which is grown an N doped silicon epitaxial layer 202. A patterned first masking material layer 203 of a silicon oxide (typically silicon dioxide) with initial apertures 205i is formed on the epitaxial layer 202. A patterned layer of photoresist material, such as a positive photoresist material, is then provided over the resulting first mask oxide layer. Subsequently, the oxide layer is anisotropically etched through apertures in the patterned layer of photoresist material using a dry oxide etch as is known in the art, producing a patterned first mask oxide layer 203 with initial apertures 205i. A further layer of NSG is deposited over the patterned first mask oxide layer 203 of FIG. 1A, followed by densification, to form an additional mask oxide layer. The mask oxide layer is then anisotropically etched, for example by using a dry oxide etch, until portions 202p of the epitaxial layer 202 are exposed, along with upper portions of the patterned first mask oxide layer 203. This etching process leaves behind sidewall spacer portions 203s, formed from the additional mask oxide layer 203, which are adjacent to the sidewalls of the initial apertures 205i. In this way, a ‘two-component’ masking layer consisting of both the patterned first mask oxide layer 203 and sidewall spacers 203s is formed. This two-component masking layer contains final apertures 205f. The silicon epitaxial layer 202 is then anisotropically etched, for example by reactive ion etching, through the final apertures 205f in the two-component oxide mask (which includes both the patterned first mask oxide layer 203 and the sidewall spacers 203s), resulting in trenches 207 as shown in FIG. 1A. These widths of the trenches 207 reflect the final apertures 205f that are substantially narrower than the initial apertures 205i.

Narrow trench widths are useful in connection with trench MOSFET devices in that the gate-drain charges associated with such devices are reduced, among other effects. As a specific example, FIG. 1B illustrates part of the narrow trench MOSFET structure disclosed in the same patent U.S. Pat. No. 6,977,203. An N doped epitaxial layer 202 is initially grown on an N+ doped substrate 200. A P-type region 204 is then formed in upper portion of the epitaxial layer 202 by implantation and diffusion. Subsequently, a two-component trench mask including both a patterned mask oxide layer 203 and oxide sidewall spacer portions 203s is formed as discussed above in connection with FIG. 1A. Trenches are then etched as discussed in connection with FIG. 1A above. Discrete P-type regions 204 are established as a result of this trench-forming step. The two-component trench mask is then removed and an oxide layer 210 is grown over the surface of the device, typically by dry oxidation at elevated temperature. Portions of the oxide layer 210 ultimately form the gate oxide regions for the finished device. The surface of the structure is then covered, and the trenches are filled, with a polysilicon layer, typically using CVD. The polysilicon is typically doped N-type to reduce its resistivity. The polysilicon layer is then etched, forming polysilicon gate regions 211. Subsequently, n+ source regions 212 are formed in upper portions of the epitaxial layer via an implantation and diffusion process. The BPSG (borophosphosilicate glass) regions 216 are then formed. The formation processes typically include processing steps of deposition, masking and etching processes, covering polysilicon regions 211 and a portion of the oxide regions 210. Finally a metal contact layer, e.g., aluminium, is deposited, forming source contact 218. The resulting structure is shown in FIG. 1B. A separate metal gate contact is also typically connected to a gate runner portion of the polysilicon that is located outside of the cell region of the trench MOSFET (not shown). Furthermore, a metal drain contact is also typically provided in connection with the semiconductor substrate (not shown).

Unfortunately, a trench profile formed to define narrow trenches, such as that described in the U.S. Pat. No. 6,977,203 and also illustrated in FIG. 1A and FIG. 1B above, usually results in a much narrower trench bottom as compared to the top of the trench. The narrower trench at the bottom limits oxygen diffusion into the trench bottom and thus causing a much thinner thermal gate oxide thickness at the trench bottom and its vicinity. This again will potentially contribute to a much higher gate charge with a trench configuration as that shown in FIG. 2.

Therefore, there is still a need in the art of the semiconductor device fabrication, particularly for trenched power MOSFET design and fabrication, to provide new and improved fabrication process that would resolve these difficulties and design limitations.

### SUMMARY OF THE PRESENT INVENTION

According to an embodiment of the invention, a method of forming a trench within a semiconductor substrate is provided. The method comprises processing steps of: (a) providing a first masking material layer over the said epitaxial layer; (b) providing the patterned first and second masking material layers with a substantial first thickness of masking material layer remains; (c) depositing a third masking material layer over said first and second masking material layer in the first aperture; (d) etching the third masking material layer until a second aperture that is narrower than the first aperture is created in the third masking material within the first aperture; e) etching the remaining thickness of first masking material layer in the second aperture until the third aperture is formed; and (f) etching the semiconductor substrate through the third aperture such that a trench is formed in the semiconductor substrate.

The first, second and third masking material layers are preferably of the different material composition and preferably having different etch selectivity to each material layer typically silicon oxide, silicon oxynitride (or silicon nitride) and polysilicon layers respectively} and are preferably etched in anisotropic etching processes.

The substrate is preferably a silicon substrate and is preferably etched in an anisotropic, reactive ion etching process.

The first trench mask aperture can range, for example, from 0.18 to 0.2 microns across in smallest dimension, while the second and third trench mask apertures can range, for example, from 0.07 to 0.13 microns across in smallest dimension.

Preferably, the patterned first and second masking material layer is provided over the semiconductor substrate by a method comprising: (a) providing a first masking material layer over the semiconductor substrate; (b) providing a second masking material layer over the first masking material layer; (c) applying a patterned photoresist layer (preferably a positive photoresist layer) over the second masking material layer; and (d) etching the second masking material layer through an aperture in the patterned photoresist layer and continued by etching the second masking material layer partially such until a substantial thickness of the first masking material layer is remained that the first aperture is formed in the first and second masking material layer. The first masking material layer thickness remained in the first aperture should be of sufficient thickness so that it can act as a hard mask when the semiconductor substrate is etched through during the final trench formation. Preferably, the third masking material should be deposited conformally in and outside of the first aperture so that a vertical sidewall spacer can best be formed when etching the third masking material layer.

The method of the present invention is useful in forming trench MOSFET devices. According to one embodiment of the invention, a trench MOSFET device is formed by a method comprising: (a) providing a semiconductor wafer of first conductivity type; (b) depositing an epitaxial layer of first conductivity type over the wafer, the epitaxial layer having a lower majority carrier concentration than the wafer; (c) forming a body region of second conductivity type within an upper portion of the epitaxial layer; (d) providing a patterned first and second masking material layer over the epitaxial layer, the pattered first masking material layer comprising a first aperture; (d) depositing a third masking material layer over the first and second masking material layer; (e) etching the third masking material layer until a second aperture that is narrower than the first aperture is created in the third masking material layer within the first aperture; (f) etching the remaining first masking material layer in the second aperture until the third aperture is formed which has the same size or smaller than the second aperture; (g) forming a trench in the epitaxial layer by etching the semiconductor wafer through the third aperture; (h) forming an insulating layer lining at least a portion of the trench; (i) forming a conductive region within the trench adjacent the insulating layer; and (j) forming a source region of first conductivity type within an upper portion of the body region and adjacent the trench. Preferably, the semiconductor wafer and the epitaxial layer are formed from silicon, and the first, second and third masking material layers are preferably formed from different material composition such that they have different etch selectivity to each other.

One advantage of the present invention is that trenches with narrow widths can be formed within a semiconductor substrate.

Another advantage of the present invention is that a trench MOSFET device can be formed with narrow trenches, and hence reduced gate charges.

Another advantage of the present invention is that trench masks can be formed having apertures that are smaller than those directly obtainable from photolithographic processing.

Another advantage of the present invention is that a more vertical final trench profile can be formed within a semiconductor as compared to the trenches formed by using the techniques disclosed by U.S. Pat. No. 6,977,203 with the formation of a tapered trench profile.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a schematic cross-sectional view of a narrow trench formation in the prior art.

FIG. 1B is a schematic cross-sectional view of a narrow trench MOSFET device in the prior art.

FIG. 2 is a schematic cross-sectional view of a tapered narrow trench profile expected by using method described in the prior art.

FIGS. 3A through 3E are schematic cross-sectional views illustrating a process for forming a narrow trench, according to an embodiment of the present invention.

FIGS. 4A and 4B are schematic cross-sectional views illustrating a method of increasing sidewall spacer width, according to an embodiment of the present invention.

FIGS. 5A through 5C are schematic cross-sectional views illustrating a method of masking a trench MOSFET device, according to an embodiment of the present invention.

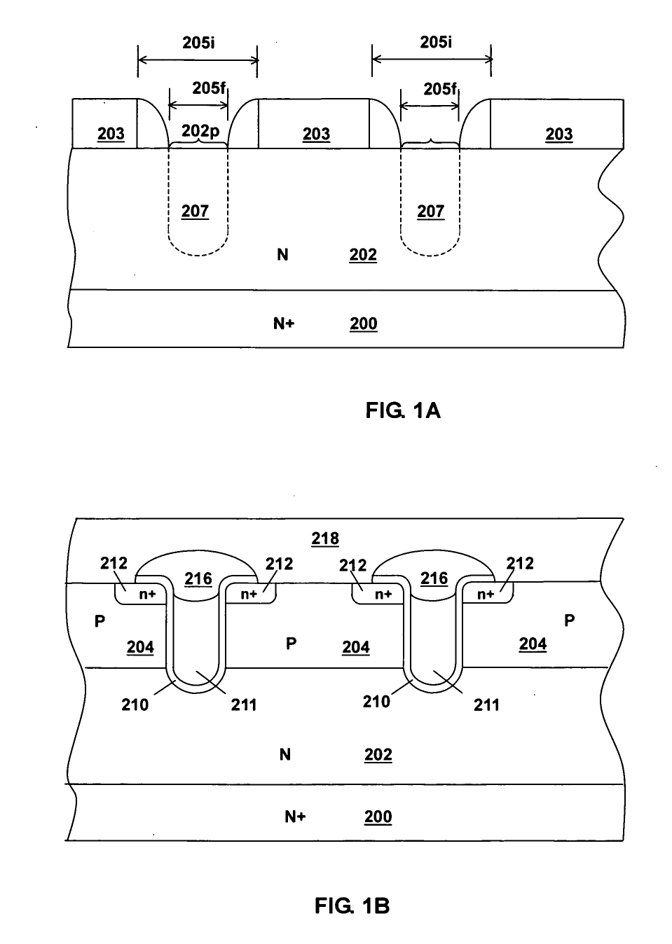

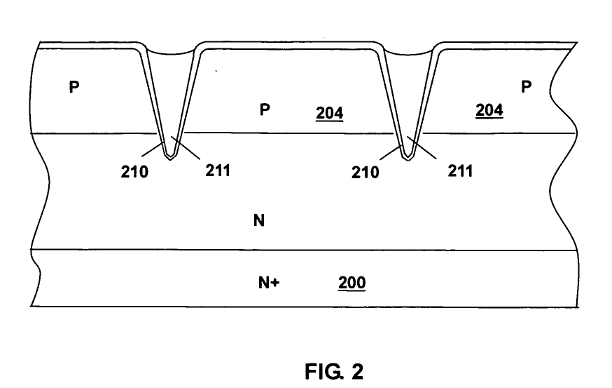

### DETAILED DESCRIPTION OF THE PREFERRED EMBODIMENT

The present invention now will be described more fully hereinafter with frequent reference to the accompanying drawings, in which preferred embodiments of the present invention are shown. This invention may, however, be embodied in different forms and should not be construed as limited to the embodiments set forth herein.

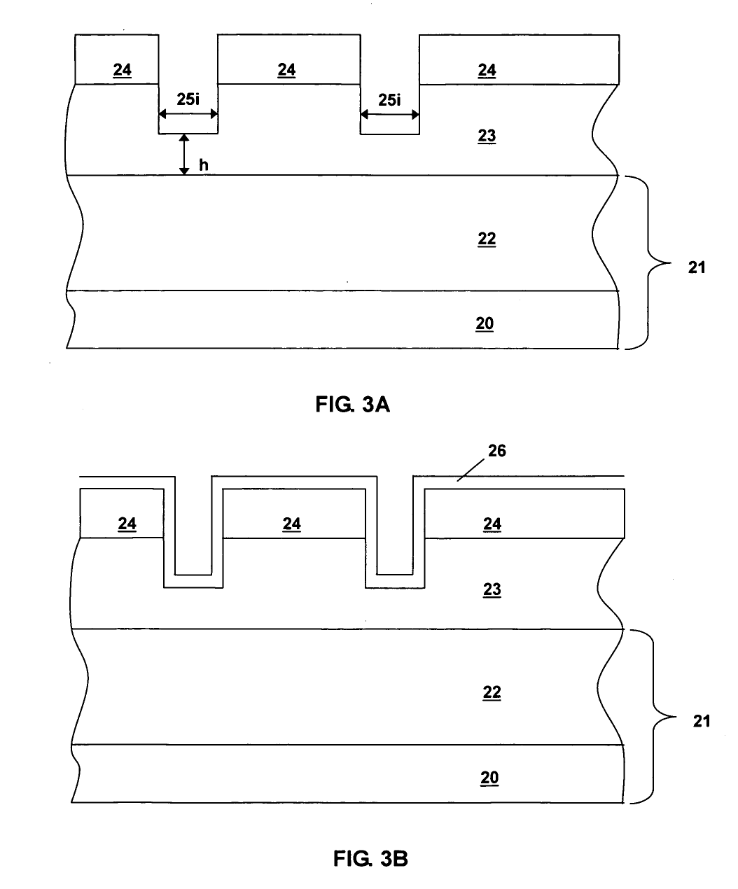

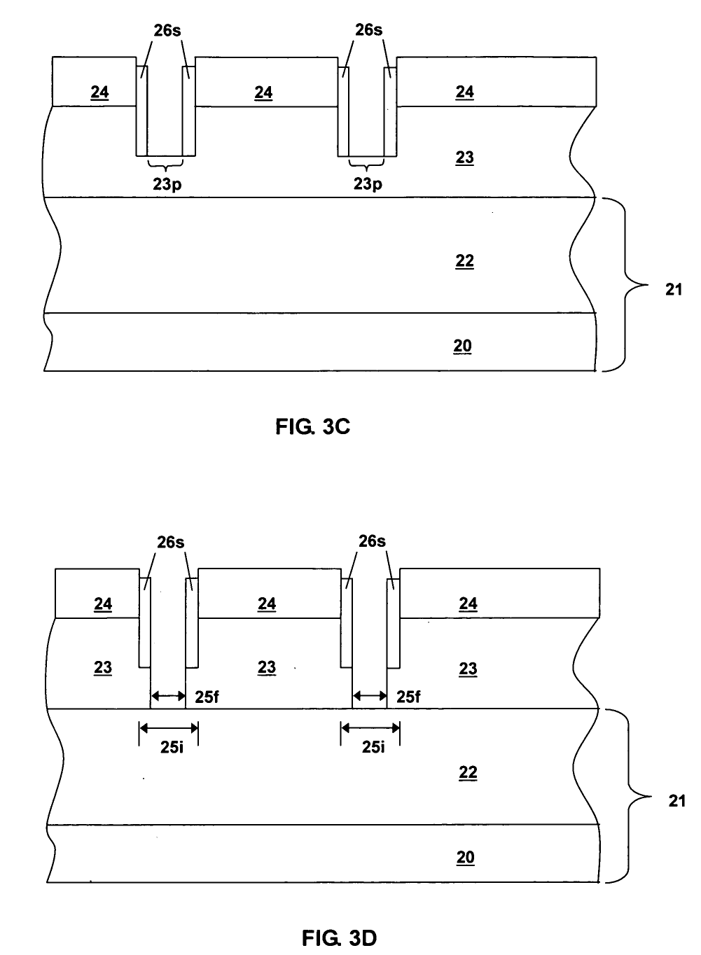

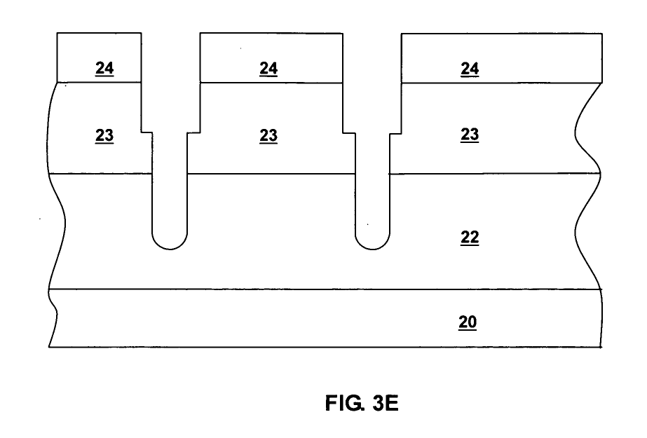

According to an embodiment of the present invention, a semiconductor substrate is the preferred substrate. This semiconductor substrate can be any such substrate known in the art, including elemental semiconductor substrates, such as silicon or germanium, or compound semiconductor substrate, such as GaAs, AlAs, GaP, InP, GaAlAs, and so forth. The semiconductor substrate can be single crystal, polycrystalline and/or amorphous, and it can be doped or undoped. A specific example of a semiconductor substrate is presented in connection with FIGS. 3A through 3E. Referring to FIG. 3A, a silicon semiconductor substrate 21 is shown, which consists of an N+ doped silicon wafer 20 having an N doped silicon epitaxial layer 22 disposed thereon.

Once the substrate is selected, a first layer of a masking material that is appropriate for forming a trench mask is provided on the substrate and patterned using any appropriate technique known in the art. For example, a first masking material layer can be provided on the substrate, followed depositing a second masking material layer on top of the first masking material. And an appropriately patterned photoresist layer can then be provided over the second masking material layer, followed by etching under conditions that etch the second masking material layer and partially etching the first masking material layer but do not substantially etch the photoresist material. The etching of the second masking material layer and partially etching the first masking material layer can be divided into 2 steps with different etching chemistry. After these etching steps, the first layer of masking material contains one or more first mask apertures. Preferred materials for the masking materials include CVD deposited materials, such as nitrides (e.g., silicon oxynitride or silicon nitride) and oxides (e.g., silicon dioxide).

Referring again to the specific example of FIGS. 3A-3E for purposes of illustration, a patterned first masking material layer 23 of a silicon oxide (typically silicon dioxide) and second masking material layer 24 with initial apertures 25i is formed in the first masking material 23 as seen in FIG. 3A. A preferred technique for providing such a patterned first and second masking layer 23 is as follows: first, a silicon dioxide layer is provided by depositing a non-doped silica glass (NSG) layer using techniques well known in the art. The deposition of such a layer is typically followed by a high-temperature annealing step, during which step the silicon dioxide layer is densified. A thin layer of silicon oxynitride (SiON) is subsequently deposited on top of the NSG layer. A patterned layer of photoresist material, such as a positive photoresist material, is then provided over the resulting oxynitride layer. Subsequently, the oxynitride is anisotropically etched through apertures in the patterned layer of photoresist followed by anisotropic etching of oxide layer until a specified thickness of oxide layer, h remains as shown in FIG. 3A producing a patterned first masking layer of oxide/oxynitride layer with initial apertures of 25i. Using well-established 0.18-micron semiconductor technology, for example, this step typically results in minimum reproducible initial apertures 25i of about 0.2 micron.

As a next step, an additional layer of material with good conformality, such as polysilicon (which can be doped or undoped, polycrystalline or amorphous) is deposited over the patterned first and second masking material layer. Due to the good conformality of this material, very good thickness uniformity can be achieved on the sidewall, trench bottom and outside the trench as depicted in FIG. 3B. The additional polysilicon layer is then etched, (typically using conditions with good selectivity to materials 23 and 24), until portions of the layer material 23 are exposed within the initial mask apertures. At the same time, unetched portions of the additional masking material layer remain within the initial trench mask apertures adjacent to the sidewall of the apertures forming the second apertures as shown in FIG. 3C. These remaining portions are referred to herein as “sidewall spacers”. The exposed layer 23 can now be etched through by anisotropic oxide etch which has good selectivity to material 26 as shown in FIG. 3B and preferably with relatively good selectivity to material 24, until portions of semiconductor substrate are exposed within the apertures forming the third apertures as shown in FIG. 3D.

Referring back to FIGS. 3A-3E as a specific example, a further layer of polysilicon is deposited over the patterned first mask oxide/oxynitride layer 23/24 of FIG. 3A, to form a polysilicon layer 26. This mask polysilicon layer 26 is then anisotropically etched, for example by using a dry poly etch, until portions 23p of the NSG layer 23 are exposed, along with upper portions of the patterned first mask oxynitride layer 24, as shown in FIG. 3C. This etching process leaves behind sidewall spacer portions 26s, formed from the additional mask polysilicon layer 26, which are adjacent to the sidewalls of the initial apertures 25i. Subsequently, the remaining layer 23 exposed within the second aperture 23p is etched using oxide dry etch process until portions of the epitaxial layer are exposed. The oxide etch condition used herein has very good etch selectivity to silicon and relatively good selectivity to SiON. In this way, a ‘three-component’ masking layer consisting of both the patterned first mask oxide/oxynitride layer, sidewall spacers 26s and final oxide hard mask 23p is formed. This three-component masking layer contains final apertures 25f that are substantially narrower than the initial apertures 25i. In the case where initial apertures 25i are provided at the limit of the photolithographic technology available, the present invention provides a way of relating final mask apertures 25f that are beyond this limit. Using 0.18-micron technology as an example, final mask apertures 25f of about 0.07 microns can be produced.

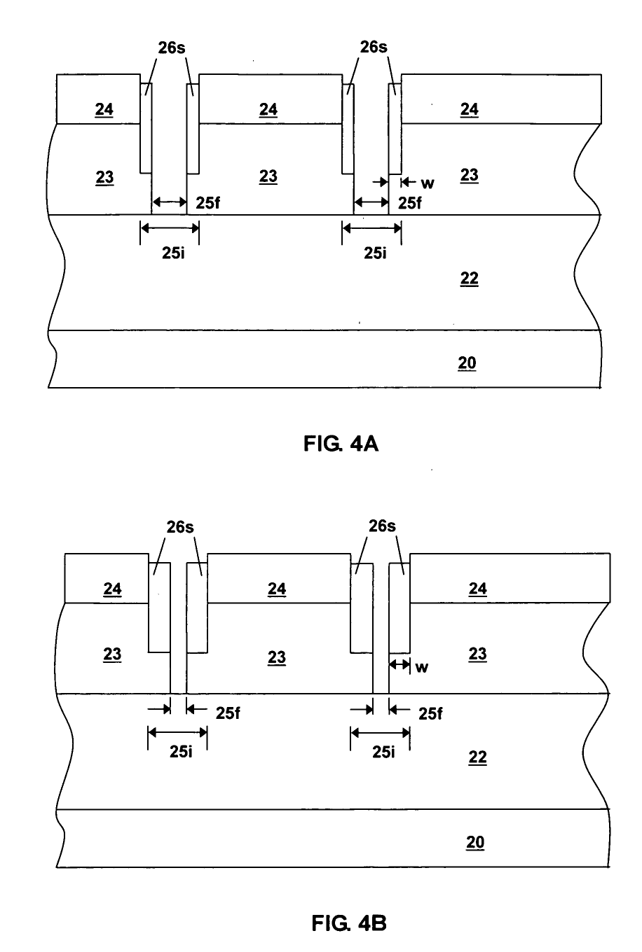

An embodiment of the present invention in which the widths of the sidewall spacers 26s (and consequently the dimension of the final aperture 25f) can be varied will now be discussed. In this embodiment, the increase in thickness of the material layer 26 causes the widths of the sidewall spacers 26s to increase. This effect is illustrated in FIGS. 4A and 4B in which two initial trench mask apertures 25i of the same width are produced within patterned mask oxide/oxynitride layers 23/24. Subsequently, an additional layer of masking material is provided and etched as described above, producing sidewall spacers 26s. The patterned sidewall spacers 26s in FIG. 4A are substantially thinner than the patterned sidewall spacers 26s in FIG. 4B. Under these circumstances, and because the profiles of the sidewall spacers 26s are relatively similar (from a geometric standpoint) in shape, the widths w of the sidewall spacers in FIG. 4A are substantially smaller (and hence the apertures 25f are substantially larger) than those in FIG. 4B.

Once the three-component trench mask is formed in accordance with the present invention, the semiconductor substrate is etched through the final apertures in the mask using an etching process by which the semiconductor material is selectively etched relative to the trench mask.

Referring once again to the specific example of FIGS. 3A-3E, the silicon epitaxial layer 22 is anisotropically etched, for example by reactive ion etching, through the final apertures 25f in the three-component hard mask (which includes both the patterned mask oxide/oxynitride layer 23/24, the sidewall spacers 26s and the final oxide hard mask 23p), resulting in trenches 27 as shown in FIG. 3E. These widths of the trenches 27 reflect the final apertures 25f, rather than the initial apertures 25i.

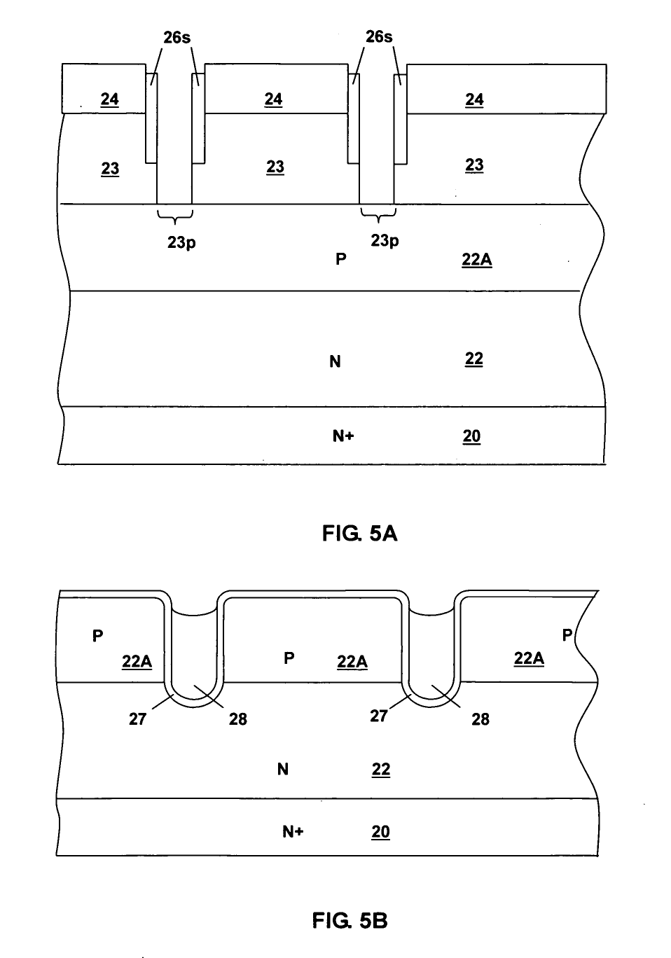

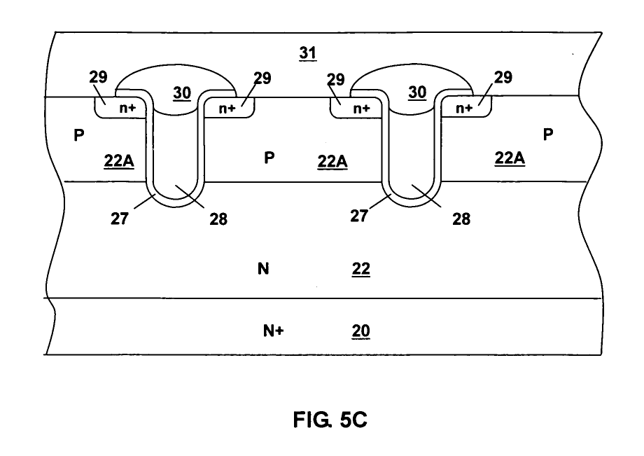

As noted above, narrow trench widths are useful in connection with trench MOSFET devices in that the gate-drain charges associated with such devices are reduced, among other effects. A method of forming a typical trench MOSFET device that incorporates the two-component trench mask of the present invention is briefly discussed here in connection with FIGS. 5A-5C.

Turning now to FIG. 5A, an N doped epitaxial layer 22 is initially grown on an N+ doped substrate 200. A P-type region 22A is then formed in upper portion of the epitaxial layer 22 by implantation and diffusion. Subsequently, a three-component trench mask including both a patterned mask oxide/oxynitride layer 23/24, sidewall polysilicon spacer portions 26s and final oxide hard mask 23p is formed as discussed above in connection with FIGS. 3A-3D. The resulting structure is shown in FIG. 5A.

Trenches are then etched as discussed in connection with FIG. 3E above. Discrete P-type regions 22A are established as a result of this trench-forming step. The three-component trench mask is then removed and an oxide layer 27 is grown over the surface of the device, typically by dry oxidation at elevated temperature. Portions of the oxide layer 27 ultimately form the gate oxide regions for the finished device. The surface of the structure is then covered, and the trenches are filled, with a polysilicon layer, typically using CVD. The polysilicon is typically doped N-type to reduce its resistivity. The polysilicon layer is then chemical mechanically polished (CMP), forming polysilicon gate regions 28. The resulting structure is shown in FIG. 5B.

Subsequently, n+ source regions 29 are formed in upper portions of the epitaxial layer via an implantation and diffusion process. The formation of the BPSG (borophosphosilicate glass) regions 30 typically includes the processing steps of deposition, masking and etching processes, covering polysilicon regions 28 and a portion of the oxide regions 27. Finally a metal contact layer (e.g., aluminium) is deposited, forming source contact 31. The resulting structure is shown in FIG. 5C. A separate metal gate contact is also typically connected to a gate runner portion of the polysilicon that is located outside of the cell region of the trench MOSFET (not shown). Furthermore, a metal drain contact is also typically provided in connection with the semiconductor substrate (not shown).

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A method of forming a trench MOSFET comprising:
providing a semiconductor wafer of a first conductivity type;
depositing an epitaxial layer of said first conductivity type over said wafer, said epitaxial layer having a lower majority carrier concentration than said wafer;
forming a body region of a second conductivity type within an upper portion of said epitaxial layer;
providing a first masking material layer over the said epitaxial layer; said first masking material layer comprises of a densified non-doped silica glass layer;
providing a second masking material layer over the said first masking material layer; said second masking material layer comprises of silicon oxynitride or silicon nitride layer;
providing the patterned first and second masking material layers; said patterned first and second masking material layers comprising a densified non-doped silica glass layer and silicon oxynitride layer respectively overlaid by a positive photoresist material, and said patterned masking material layers comprising a first aperture within the first and second masking material layer;
depositing a third masking material layer over said first and second masking material layer, said third masking material layer comprising a doped polysilicon layer;
etching said third masking material layer until a second aperture is created in said second masking material layer within said first aperture, said second aperture being narrower than said first aperture;
etching the remaining stack of first masking material layer within the second aperture until the epitaxial layer is exposed in order to form the third oxide hard mask aperture;
forming a trench in said epitaxial layer by etching said semiconductor wafer through said third aperture of which the said second aperture formed by polysilicon spacer will be removed too; and
removing the first and second masking material layer prior to performing the following steps:
forming an insulating layer lining at least a portion of said trench; forming a conductive region within said trench adjacent said insulating layer; and
forming a source region of said first conductivity type within an upper portion of said body region and adjacent said trench, wherein said step of forming a source region is performed subsequent to said step of forming a trench.

2. The method of claim 1 wherein said patterned first and second masking material layers are provided over said semiconductor wafer by a method comprising:
providing a first masking material layer over said epitaxial layer;
providing a second masking material layer over the said first masking material layer;
applying a patterned photoresist layer over said second masking material layer;
etching said second masking material layer fully through an aperture in said patterned photoresist layer and followed by etching the said second masking material layer to a specified thickness such that said first aperture is formed in said first and second masking material layers.

3. The method of claim 1, wherein said semiconductor wafer is silicon wafer and said epitaxial layer is a silicon epitaxial layer.

4. The method of claim 1, wherein said first and second masking material layers are of the different material composition such that there will be a relatively good etch selectivity of first masking material to the second masking material.

5. The method of claim 1, wherein said first material layer is silicon dioxide layer and second masking material layer is silicon oxynitride layer.

6. The method of claim 1, wherein said process of etching said first and second masking material is an anisotropic process comprising of first a silicon oxynitride dry etching process followed by a silicon dioxide dry etching process.

7. The method of claim 1, wherein said the third masking material is a polysilicon layer (doped or undoped, polycrystalline or amorphous)

8. The method of claim 1, wherein said process of etching the third masking material layer is an anisotropic polysilicon dry etching process.

9. The method of claim 1, wherein said process of etching the remaining stack of first masking material; i.e. oxide layer is an anisotropic oxide dry etching process with relatively good selectivity to silicon oxynitride.

10. The method of claim 1, wherein said process of etching said semiconductor is an anisotropic, reactive ion etching process.

11. The method of claim 2, wherein said photoresist layer is a positive resist layer.

12. The method of claim 1, wherein said first trench mask aperture ranges from 0.18 to 0.2 microns in smallest dimension and said second trench mask aperture ranges from 0.13 to 0.07 microns in smallest dimension.
